(19) United States
(12) Patent Application Publication
(10) Pub. No.: US 2007/0048925 A1
(43) Pub. Date: Mar. 1, 2007

(54) Body-Contacted Silicon on Insulation (SOI) field effect transistors

(75) Inventors: Kevin McStay, Hopewell Junction, NY (US); Myung-Hee Na, Essex Junction, VT (US); Edward Joseph Nowak, Essex Junction, VT (US)

Correspondence Address: GREENBLUM & BERNSTEIN, P.L.C., 1950 ROLAND CLARK DRIVE, RESTON, VA, 20191, US

(73) Assignee: INTERNATIONAL BUSINESS MACHINES CORPORATION, Armonk, NY (US)

(21) Appl. No.: 11/161,973

(22) Filed: Aug. 24, 2005

(51) Int. Cl. H01L 21/8238; H01L 21/336

(52) U.S. Cl. 438/213; 438/302; 438/232; 257/E29.012

(57) ABSTRACT

An apparatus and method for reducing resistance under a body contact region. The method comprises providing a substrate including a gate structure comprising an active region and a contact body region. The method also includes forming a first impurity region under the contact body region at a higher dose than that under the active region. The resulting higher concentration is configured to lower a resistance in a body-contact parasitic region of the isolating channel region and suppresses a back-gate “sneak path’” for leakage.

### FIELD OF THE INVENTION

The invention relates to a semiconductor device, and more particularly to a method of improving body contacted silicon on insulation (SOI ) field effect transistors (FET) with the use of a halo implantation process.

### BACKGROUND DESCRIPTION

Body contacted devices in Partially-Depleted SOI, PDSOI, are key analog components used in PLLs, small-swing receivers, and the like. As is well known in the art of semiconductor fabrication, in PDSOI, the depletion/inversion layer under the gate is thinner than the Si active layer. In the body contacted devices, low-resistance contact to the body must be assured, and accurate models provided early in the program development. Increasing halo or well dose later in the program upsets the body-effect and drive of the FET. Also, such increases in the halo or well dose later in the program can require redesign of the device, with associated delay and cost.

In standard SOI FET, the source and drain are formed in an epitaxial layer of silicon disposed on the silicon oxide-insulating layer. In SOI technology, if the body of an SOI transistor device floats, e.g., is not connected to a voltage source, the device characteristics and threshold voltage may vary with the switching history which the device experiences in actual operation. To cure such deficiencies, it is known to form a contact to the body of the device in order to allow the body to be connected to a potential source. This may be done by use of a vertical gate line; however, known contact bodies have high resistance, which impart deleterious characteristics to the device.

By way of example, in known body contacts, the body contact is doped in the same concentration as that of the active region of a semiconductor device. This doping can affect many performance characteristics of the semiconductor device. For example, if the body doping concentration is increased in order to reduce the body-contact resistance, the threshold voltage of the device will increase in correspondence. Accordingly, under certain circumstances, a semiconductor device, with increased body doping to reduce body contact resistance, will tend to require higher gate voltage to conduct and to conduct less for a given voltage applied to the gate. Yet another problem for body-contacted devices is the potential for the existence of a ‘sneak path’ for current between the source and the drain adjacent to the device channel and beneath the region of the gate electrode which provides isolation between the body contact and the source/drain regions. When body doping is too low beneath this isolation region and adjacent to the source and drain regions, a parasitic channel can form between the source and drain which degrades operation of the device. This sneak path can be particularly exacerbated when the body-contacted device is operated at voltages, with respect to the substrate voltage, that tend to invert the body, providing a ‘back-gating’ action on this sneak path. Thus it is desirable to achieve low resistance the body contact, and to eliminate sneak paths, while maintaining low threshold voltage of the device.

### SUMMARY OF THE INVENTION

In a first aspect of the invention, a method of manufacturing a device includes providing a substrate including a gate structure comprising an active region and a contact body region. The method also includes forming a first impurity region under the contact body region at a higher dose than that under the active region.

In another aspect of the invention, the method comprises providing a substrate having a gate structure comprising an active gate electrode and an isolating gate electrode. The active gate electrode and the isolating gate electrode are not parallel to one another. The method further includes forming a first impurity region under an edge of the isolating gate electrode at a higher dose than that under the active gate electrode. The first impurity is not formed under the active gate electrode.

In another aspect of the invention, a semiconductor device comprises a device having an active channel region and at least one isolating channel region substantially orthogonal to the active channel region. The active channel region and the at least one isolating channel region have a doped region at a first concentration and the isolating channel region has a doped region at a second, higher concentration which does not substantially affect the active channel region of the device. The second, higher concentration is configured to lower a resistance in a body-contact parasitic region of the isolating channel region and suppress a back-gate “sneak path’” for leakage.

### BRIEF DESCRIPTION OF THE DRAWINGS

FIGS. 1-3 are cross-sectional views of an embodiment of a method of making a device in accordance with the invention;

FIG. 4 shows a top view of a first embodiment of the invention; and

FIG. 5 shows a top view of a second embodiment of the invention.

### DETAILED DESCRIPTION OF EMBODIMENTS OF THE INVENTION

The invention relates to a semiconductor device, and more particularly to a method of improving body contacted SOI FETs with a halo implantation process on the body contact region. In accordance with the invention, a channel region of an FET is formed in a first direction on the substrate (e.g., x-direction) and comprises a first halo implant in the channel region of a first dopant type at a first concentration. A body contact region is formed in another direction (e.g., y direction) and comprises a second halo implant of the first dopant type at a second concentration different than the first concentration (preferably at a higher concentration). In accordance with the invention, the second halo implant reduces body contact resistance, to name but few features.

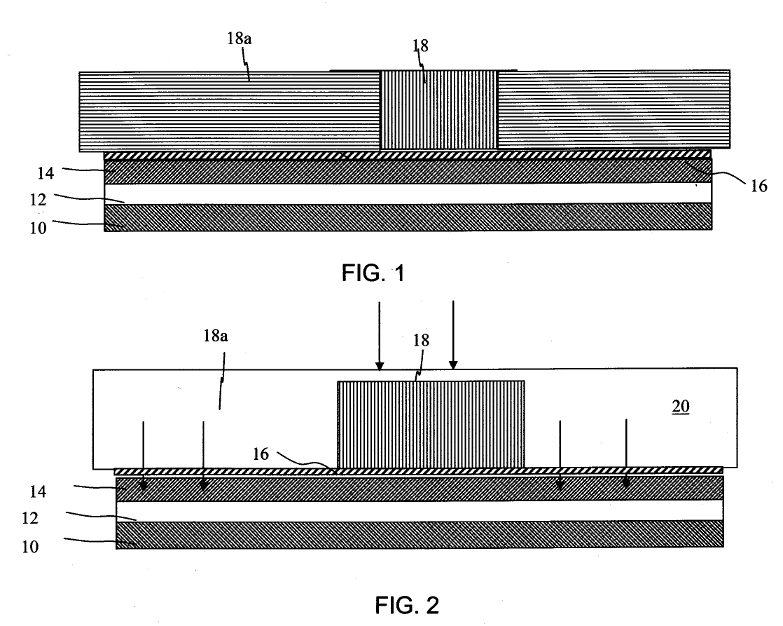

Referring to FIG. 1, an example of a starting structure for an embodiment in accordance with the invention is shown. In FIG. 1, an optional oxide BOX 12 is formed on a substrate 10 and an SOI layer 14 is formed on the optional BOX 12. A gate dielectric 16 is formed on the SOI layer 14. An active gate electrode (e.g., gate) 18 is formed on the gate dielectric 16, which includes a vertical gate line 18 (isolating gate electrode). The vertical gate line 18a is used as a body contact with the underlying substrate, as discussed in more detail below.

As should be understood, the starting structure is formed by any of the suitable methods for forming the respective structures. Thus, the gate dielectric 16 may be formed, for example, from an oxide, a nitride, or high k material, and may include SiO₂, for example. The gate 18 (and vertical gate line 18a) may be formed from, for example, a polysilicon. Also, the gate dielectric 16 may be in the range of approximately 0.7 nm to 2 nm, and may also vary from these specifications, depending on the specific applications. The gate 18 may range from about 50 nm to 150 nm in length, for example.

Referring to FIG. 2, in one embodiment, an oxidation process is performed to remove any imperfections on, and protect, the sidewalls of the poly gate 18 and the vertical gate line 18a. The oxide, in embodiments, may be grown or deposited via any well-known deposition processes to form oxide layer 20, or a combination growth and deposition may be employed. The oxide layer 20 may be in the range of, for example, 2 nm to 5 nm, although other ranges are also contemplated for use with the invention.

FIG. 2 further represents an extension implantation process for the device. In this process, a donor element such as, for example, phosphorus (P), arsenic (As), antimony (Sb), etc. is used for an nMOSFET and an acceptor element such as, for example, boron (B), indium (In), boron fluoride (BF₂), etc. is used for a pMOSFET. In one implementation, doping occurs at a common energy level and dosage, depending on a particular application. Typical dopant doses for the extension region range from 5×10¹⁴ cm⁻² to 1×10¹⁶ cm⁻². Typical dopant energy levels for the extension regions range from 0.1 keV to 10 keV, as illustrative examples.

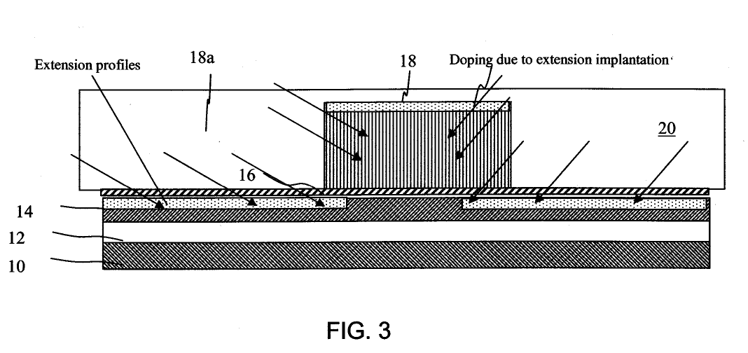

FIG. 3 shows the doping and extension profiles. In one embodiment, the ions, due to the extension implantation of FIG. 2, penetrates the gate 18 and vertical gate line 18a to about 5 nm to 10 nm. The doping, due to the extension implantation of FIG. 2, provides a profile of about 180 Å to 400 Å in the SOI layer 14. It should be understood by those of skill in the art that the profile in the SOI layer 14, as well as the profile in the gate 18 and vertical gate line 18a are one non-limiting illustrative example, and thus may vary depending on the particular energy level and dopant concentration for a specific application.

FIG. 3 also represents a halo implantation process in four directions. The halo regions may be formed by any of the standard halo implantation methods appropriate for the type of device being formed. For example, for an nFET type device, the halo regions may be formed from, for example, B, In, BF₂, etc. with doses ranging from 1×10¹³ cm⁻² to 2×10¹⁴ cm⁻², dopant energies ranging from 1 keV to 100 keV and tilt angle ranging from 10° to 50°. The tilt angle, in one embodiment, is at a different angle than that of the implant of the active region. For a pFET type device, the halo regions may be formed from, for example, P, As, Sb, etc.

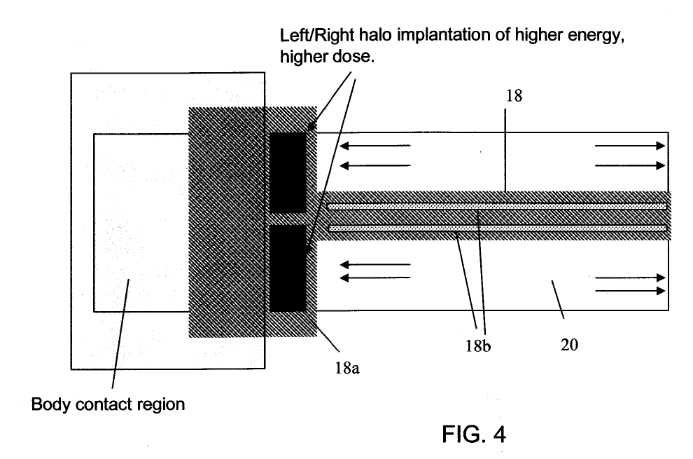

FIG. 4 represents a top view of the device in accordance with the invention. In this embodiment, a “T′ shaped gate-type device is shown. As shown in this view, an additional halo implantation process is performed on the body contact region and more particularly on the vertical gate line 18a. The halo implantation process, shown in FIG. 4, is performed parallel to the active gate region 18b. In this way, the halo implantation process does not significantly affect the active channel region 18b since the higher dose is performed substantially parallel to such region 18b, and substantially on the vertical gate line 18a (which is perpendicular to region 18b).

In one embodiment, the dose of the halo implantation is in the range of 2×10¹³ cm⁻² to about 2×10¹⁴ cm⁻² at a relatively high energy such as, for example, 120 KeV for As.

In this process, the implantation includes, for example, doping the device with a donor element, e.g., P, As, Sb, etc. for a pMOSFET device, and an acceptor element, e.g., B, In, BF₂, etc. for an nMOSFET device. Thus, the type of dopant used in the halo implantation process, in accordance with the invention, will be the type of dopants used for the initial halo implantation.

By using the halo implantation, at a higher energy and dose, it is now possible to reduce the body resistance at the bottom of the body, itself. Thus, in the method and structure of the invention, the higher dose and energy will reduce the higher resistance in the body.

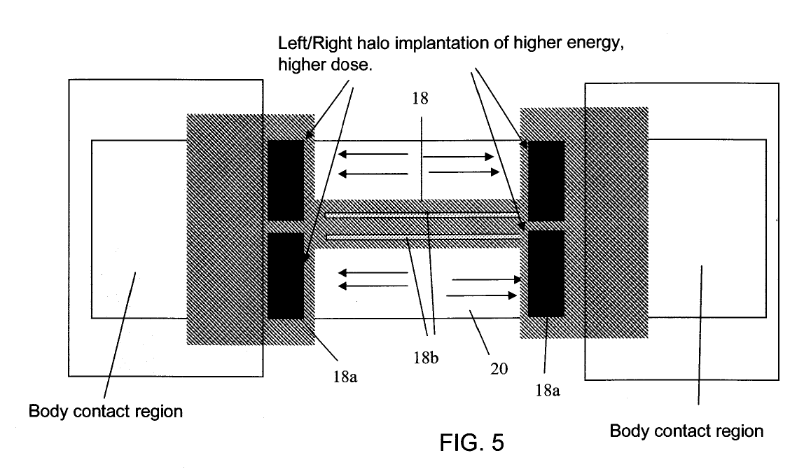

FIG. 5 represents a top view of the device in accordance with the invention. In this embodiment, an “H” shaped gate-type device is shown. As shown in this view, an additional halo implantation process is performed on the body contact region and more particularly on the vertical gate lines 18a. The halo implantation process, shown in FIG. 5, similar to that of FIG. 4, is performed substantially only on the vertical gate lines 18a. In this way, the halo implantation process does not significantly affect the active channel region 18b since the implantation is performed substantially parallel to such region 18b, and substantially on the vertical gate lines 18a (which are perpendicular to region 18b). As with the embodiment of FIG. 4, the halo implantation is also able to control the threshold voltage, as well as suppress back gate sneak path for leakage.

Also, a previously discussed, by using the halo implantation, at a higher energy and dose, it is now possible to reduce the body resistance at the bottom of the body, itself. Thus, in the method and structure of the invention, the higher dose and energy will reduce the higher resistance in the body. In one embodiment, the dose of the halo implantation is in the range of 2×10¹³ cm⁻² to about 2×10¹⁴ cm⁻² at a relatively high energy such as, for example, 120 KeV for As, and utilizing the same elements as described above.

Thus, embodiments include a method and device to provide a doping concentration in an active region of a semiconductor device with an increased doping concentration of the body contact, e.g., vertical gate line. In accordance with the invention, in the halo implantation, the ions reach though the body contact, with less dosage or concentration of implant being received in the active channel region, itself. In this way, the halo implantation process of the invention controls the threshold voltage, while reducing the contact resistance between the body contact and the lower structure. Also, by using the invention, the body contact is greatly improved over conventional devices while only minor affect to the FET by providing a strong halo ion-implant in the direction of a T or H-body gate, but only the conventional dose halo along the active gate. This provides low resistance in the body-contact parasitic region and also suppresses a back-gate “sneak path’” for leakage that has otherwise be observed in such designs.

Normal process steps to finish building devices (including spacer formation, source drain implantation, source/drain annealing, and metalization) can be implemented after the implantation steps of FIGS. 4 and 5. For example, source/drain spacers are formed on either side of the gate, above the extension regions in the substrate. The source/drain spacers may be formed by any of the standard methods for forming sidewall spacers. Source/drain regions are formed in the substrate to either side of the source/drain spacers. The source/drain region may be formed from any of the dopants appropriate for the type of device being formed. For example, for a nFET device, the source/drain region may be formed from, for example, arsenic or phosphorus. For a pFET type device, the source drain region may be formed from, for example, boron or BF₂.

While the invention has been described in terms of exemplary embodiments, those skilled in the art will recognize that the invention can be practiced with modifications and in the spirit and scope of the appended claims.

1. A method, comprising:
providing a substrate including a gate structure comprising an active region and a contact body region; and
forming a first impurity region under the contact body region at a higher dose than that under the active region.

2. The method of claim 1, wherein the forming step comprises ion implanting an impurity in a direction substantially parallel to the active region.

3. The method of claim 2, wherein the impurity is ion implanted only under the contact body region.

4. The method of claim 2, further comprising ion implanting an impurity under the active region.

5. The method of claim 4, wherein the implanting under the contact body region is at a higher dose or energy level, or angle, than under the active region.

6. The method of claim 1, wherein the forming step includes implanting an impurity under the contact body region at a dose in the range of 2×10¹³ cm⁻² to about 2×10¹⁴ cm⁻².

7. The method of claim 1, further comprising implanting an impurity under an edge of the active region and the contact body region at a first energy and dose, and the forming step comprises implanting the impurity region at a higher dose or energy level, or angle.

8. The method of claim 1, wherein the forming step comprising implanting a strong halo ion-implant in a direction of a portion of a T or H-body of the contact body region, substantially perpendicular to the active region.

9. The method of claim 1, wherein the forming step provides low resistance in a body-contact parasitic region of the contact body region.

10. The method of claim 1, wherein the forming step suppresses a back-gate “sneak path” for leakage.

11. A method, comprising:
providing a substrate having a gate structure comprising an active gate electrode and an isolating gate electrode, the active gate electrode and the isolating gate electrode are not parallel to one another; and
forming a first impurity region under an edge of the isolating gate electrode at a higher dose than that under the active gate electrode, wherein the first impurity is not directed to under the active gate electrode.

12. The method of claim 11, wherein the forming step comprising ion implanting an impurity in a direction substantially parallel to the active gate electrode.

13. The method of claim 12, wherein the impurity is ion implanted only under the isolating gate electrode.

14. The method of claim 11, further comprising ion implanting an impurity under the active gate electrode.

15. The method of claim 14, wherein the ion implanting is at a lower dose than in the forming of the first impurity region.

16. The method of claim 14, wherein the ion implanting under the active gate electrode is also performed under the isolating gate electrode.

17. The method of claim 11, wherein the forming a first impurity region includes using a first dopant comprising one of boron (B), indium (In), and boron fluoride (BF₂), or a second dopant comprising one of phosphorus (P), arsenic (As), and antimony (Sb).

18. The method of claim 11, wherein the active gate electrode forms a device for at least one of an nMOSFET and a pMOSFET, the pMOSFET is doped with one of boron (B), indium (In), and boron fluoride (BF₂) for extension regions, and the nMOSFET is doped with one of phosphorus (P), arsenic (As), and antimony (Sb) for extension regions.

19. The method of claim 11, wherein the active gate electrode is doped with an impurity that is the same for the formation of the first impurity region, at a lower dose.

20. (canceled)
